(19) United States
(12) Patent Application Publication
(10) Pub. No.: US 2025/0243000 A1
(43) Pub. Date: Jul. 31, 2025

(54) Transport Facility

(71) Applicant: Daifuku Co., Ltd., Osaka-shi (JP)

(72) Inventors: Kosuke Sakamoto, Hinocho (JP); Tomoaki Nishikawa, Hinocho (JP); Yoshitaka Tanaka, Hinocho (JP); Yuka Sasaki, Hinocho (JP); Kazuhiro Hayami, Hinocho (JP); Hiroshi Otsuka, Hinocho (JP)

(21) Appl. No.: 19/036,508

(22) Filed: Jan. 24, 2025

(30) Foreign Application Priority Data
Jan. 29, 2024 (JP) 2024-011116

(51) Int. Cl. B65G 1/04; B65G 1/137

(52) U.S. Cl. CPC B65G 1/0457; B65G 1/1373

(57) ABSTRACT

A transport facility includes a plurality of transport vehicles that transport articles and a control system that controls the transport vehicles. Each transport vehicle includes a transporter. The control system performs, in response to electric power supply to the transport vehicles being interrupted, an interruption information obtaining process of obtaining an operating state information of each transport vehicle as preliminary operating state information. The control system performs, after the electric power supply is restored, a post-restoration information obtaining process of obtaining the operating state information of each transport vehicle as post-restoration operating state information. The control system performs an automatic recovery target determination process of determining whether each transport vehicle is a target of automatic recovery based on a result of comparison between the preliminary operating state information and the post-restoration operating state information.

### CROSS-REFERENCE TO RELATED APPLICATION

This application claims priority to Japanese Patent Application No. 2024-011116 filed Jan. 29, 2024, the disclosure of which is hereby incorporated by reference in its entirety.

### BACKGROUND OF THE INVENTION

### Field of the Invention

The present invention relates to a transport facility.

### Description of Related Art

For example, Japanese Unexamined Patent Application Publication No. 10-111716 (JP 10-111716) describes a technique for a transport facility. Reference signs in parentheses used hereafter in describing the background are the reference signs in JP 10-111716.

A transport facility described in JP 10-111716 includes multiple transport vehicles (transport devices 4) that travel along a travel path (1), multiple stations (ST) arranged along the travel path (1), and a travel controller (5) that controls the multiple transport vehicles. Each of the multiple transport vehicles travels with external electric power supply and transports articles between the multiple stations (ST). Each transport vehicle includes a controller (13) that controls the travel of the transport vehicle, a travel encoder (19) for detecting the traveling position of the transport vehicle, and an emergency battery (34). When the external electric power supply is interrupted due to, for example, a power outage, the transport vehicle loses a driving force for traveling and stops. When the external electric power supply is interrupted, however, the emergency battery (34) supplies electric power to the controller and the travel encoder (19) for a predetermined period. The transport vehicle can thus store its stop position into a nonvolatile memory (21) included in the controller.

In the transport facility described in JP 10-111716, each of the multiple transport vehicles stores its stop position when the external electric power supply is interrupted. This allows the transport vehicles to resume transporting articles 7 immediately after the electric power supply is restored and thus can improve the operating rate of the facility. However, some transport vehicles in specific states may cause an additional failure when resuming transporting the articles 7 immediately after the electric power supply is restored. For example, a transport vehicle that is moved manually to a different stop position after the external electric power supply is interrupted and before the electric power supply is restored, or a transport vehicle that has detected an abnormality may cause another abnormality or issue when such transport vehicles resume transporting the articles immediately. This may reduce the operating rate of the facility.

### SUMMARY OF THE INVENTION

Techniques are awaited for appropriately recovering, when electric power supply to the transport vehicles is interrupted at a transport facility including multiple transport vehicles that transport articles, the states of the transport vehicles after the electric power supply is restored and reducing the likelihood of another failure.

A transport facility according to an aspect of the disclosure includes a plurality of transport vehicles that transport articles, a control system that controls the plurality of transport vehicles, and a power feeder that supplies electric power to the plurality of transport vehicles and the control system. Each of the plurality of transport vehicles includes a transporter operable to transport the articles. The control system obtains operating state information indicating an operating state of the transporter in each of the plurality of transport vehicles. The control system performs an interruption information obtaining process, a post-restoration information obtaining process, an automatic recovery target determination process, and an automatic recovery process. The interruption information obtaining process is a process of obtaining, in response to electric power supply to the plurality of transport vehicles being interrupted, the operating state information of each of the plurality of transport vehicles as preliminary operating state information and storing the obtained preliminary operating state information within a period after the electric power supply is interrupted and before the transporter stops operating. The post-restoration information obtaining process is a process of obtaining, after the electric power supply is restored, the operating state information of each of the plurality of transport vehicles as post-restoration operating state information. The automatic recovery target determination process is a process of determining whether each of the plurality of transport vehicles is a target of automatic recovery based on a result of comparison between the preliminary operating state information and the post-restoration operating state information. The automatic recovery process is a process of controlling, among the plurality of transport vehicles, a transport vehicle determined to be the target of the automatic recovery through the automatic recovery target determination process, and causing the transport vehicle to resume operating in a same manner as before the electric power supply is interrupted.

This structure can determine whether each of the plurality of transport vehicles is a target of automatic recovery when the electric power supply to the transport vehicles is interrupted due to, for example, a power outage and then restored. The automatic recovery process can thus be simply performed on transport vehicles in a state appropriate for the automatic recovery and not on transport vehicles in a state inappropriate for the automatic recovery.

This can reduce the workload of an operator compared with when the operator manually performs the recovery process on all transport vehicles, and can also reduce the likelihood of additional abnormality or issues resulting from the automatic recovery process performed on the transport vehicles in a state inappropriate for the automatic recovery.

Additionally, this structure allows the transport vehicle determined to be a target of the automatic recovery to resume operating in the same manner as before the electric power supply is interrupted, and thus can appropriately recover the state before the electric power supply is interrupted. The automatic recovery can thus be easily performed on the plurality of transport vehicles.

As described above, this structure can appropriately recover the states of the transport vehicles when the electric power supply to the transport vehicles is interrupted and then restored, and can reduce the likelihood of another failure.

Further aspects and advantages of the transport facility will be apparent from exemplary and nonlimiting embodiments described below with reference to the drawings.

### BRIEF DESCRIPTION OF THE DRAWINGS

FIG. 1 is a control block diagram.

FIG. 2 is a schematic diagram of a transport facility showing its overall structure.

FIG. 3 is a side view of a transport vehicle.

FIG. 4 is a front view of the transport vehicle.

FIG. 5 is a schematic side view of the transport vehicle in an operation of transferring an article.

FIG. 6 is a control flowchart.

FIG. 7 is a control flowchart.

FIG. 8 is a control flowchart.

FIG. 9 is a control flowchart.

FIG. 10 is a schematic plan view of transport vehicles traveling in an automatic recovery process.

FIG. 11 is a control flowchart in another embodiment.

### DESCRIPTION OF THE INVENTION

### First Embodiment

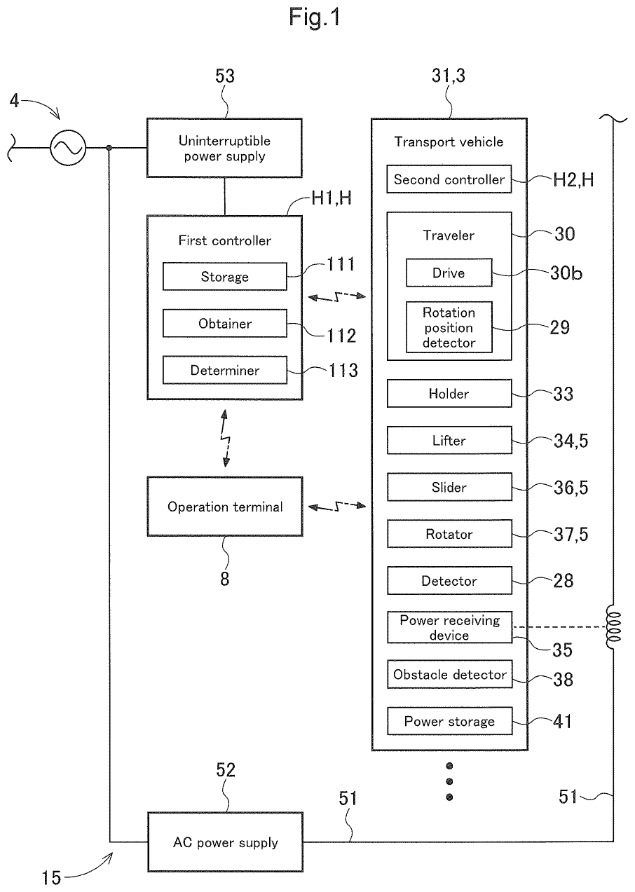

A transport facility according to a first embodiment will be described with reference to the drawings. As shown in FIG. 1, a transport facility 100 includes multiple transport vehicles 3 that transport articles 7, a control system H that controls the transport vehicles 3, and a power feeder 15 that supplies electric power to the transport vehicles 3 and the control system H. In the present embodiment, the power feeder 15 includes a power receiver 4 that receives electric power from outside the transport facility 100, an alternating current (AC) power supply 52 and feed lines 51 for supplying electric power to the multiple transport vehicles 3, and an uninterruptible power supply 53. The power feeder 15 also includes a power transmission network other than the above components arranged in the transport facility 100. The control system H includes a first controller H1 that controls the multiple transport vehicles 3 and second controllers H2 included in the respective transport vehicles 3.

The power receiver 4 is a facility that receives electric power supplied from a system power supply (utility power supply). The power receiver 4 supplies electric power to each of the first controller H1 and the AC power supply 52. In this example, the uninterruptible power supply 53 supplies electric power to the first controller H1 for a predetermined period when the electric power supply from the power receiver 4 is interrupted.

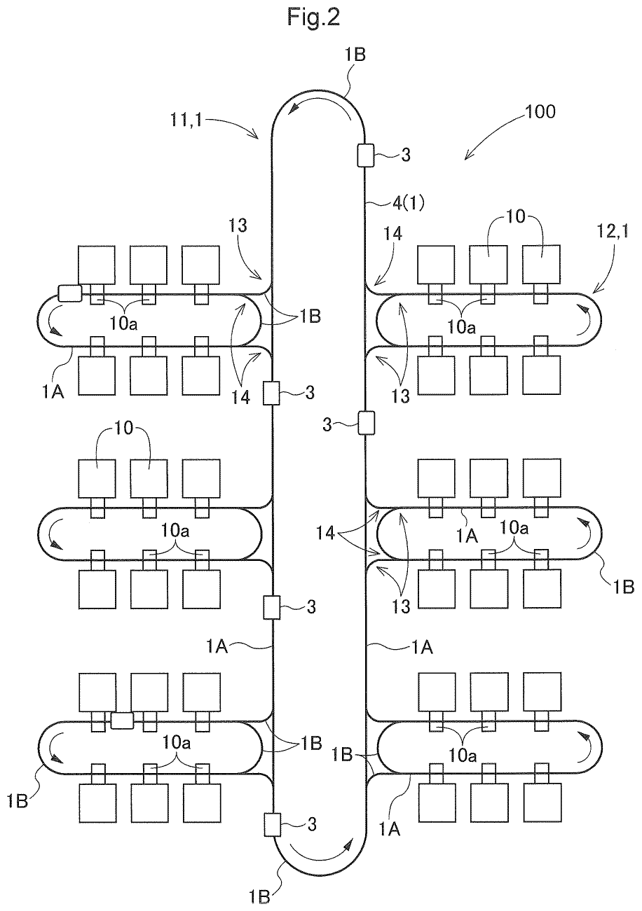

As shown in FIG. 2, each of the multiple transport vehicles 3 travels along a preset travel path 1 to transport an article 7. The feed lines 51 are connected to the AC power supply 52 and extend along the travel path 1. Each of the multiple transport vehicles 3 travels along the travel path 1 while receiving electric power for driving from the feed lines 51.

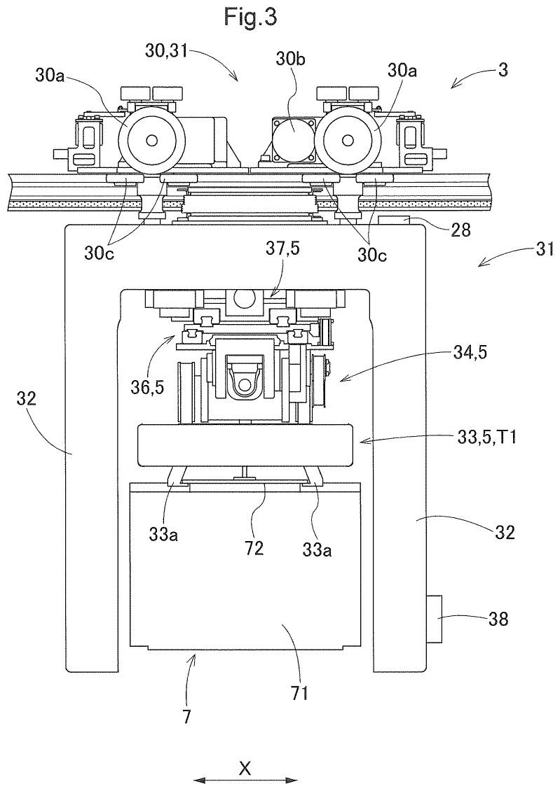

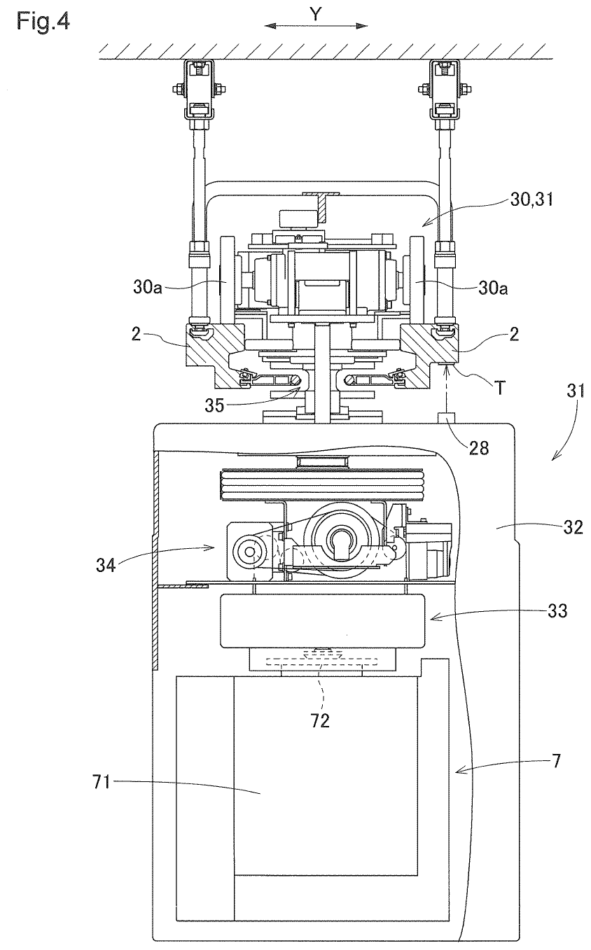

The transport vehicles 3 transport the articles 7 to multiple transfer areas 10a arranged along the travel path 1. In this example, as shown in FIG. 2, multiple processing devices 10 are arranged along the travel path 1. In this example, the transfer areas 10a for the articles 7 are load ports (mounts on which the articles 7 are placed) for the processing devices 10. Each transport vehicle 3 stops at a position corresponding to a transfer area 10a on the travel path 1 to transfer an article 7. In the present embodiment, as shown in FIGS. 3 to 5, travel rails 2 extend along the travel path 1. Each transport vehicle 3 travels on the travel path 1 as guided by the travel rails 2. As shown in FIGS. 4 and 10, multiple detectable members T are disposed at respective predetermined positions on the travel path 1. In this example, the detectable members T are arranged on the travel rails 2. Each detectable member T includes position information (address information) about the travel path 1. The detectable members T are detected by the transport vehicles 3 traveling on the travel rails 2.

As shown in FIG. 2, the travel path 1 includes a single looped primary path 11 and looped secondary paths 12 each extending through multiple processing devices 10. The travel path 1 includes straight sections 1A and curved sections 1B. The primary path 11 and the secondary paths 12 are connected to each other with branching paths 13 at which the primary path 11 branches into the secondary paths 12 and merging paths 14 at which the secondary paths 12 merge into the primary path 11. In the illustrated example, each secondary path 12 also includes a branching path 13 at which the straight section 1A branches into the curved section 1B and a merging path 14 at which the curved section 1B merges into the straight section 1A. The transport vehicles 3 travel along the primary path 11 and the multiple secondary paths 12 in the same circumferential direction (counterclockwise in the example in FIG. 2). As shown in FIG. 10, the detectable members T are arranged near portions of sections (the straight sections 1A in this example) adjacent to the branching paths 13 or the merging paths 14. The detectable members T are also arranged, on the travel path 1, at positions corresponding to the transfer areas 10a (load ports) for the processing devices 10.

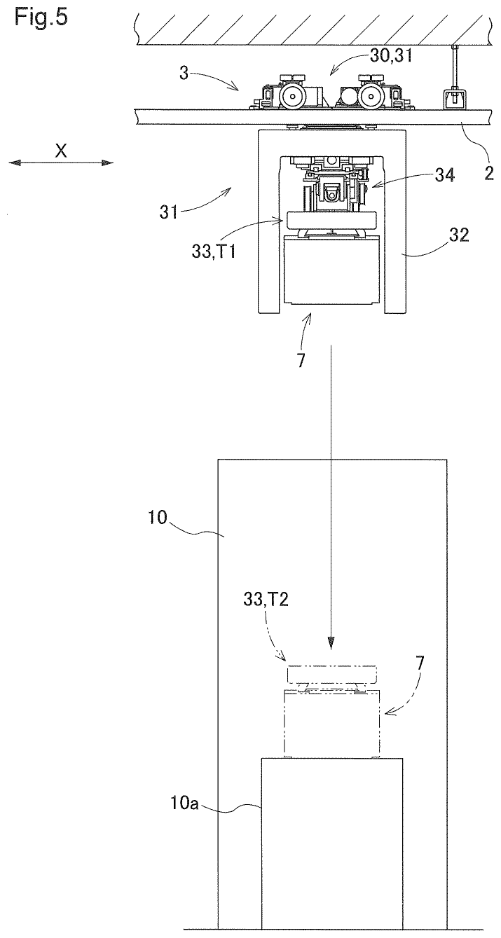

In the present embodiment, the travel path 1 extends along the ceiling of the transport facility 100. Thus, the travel rails 2 also extend along the ceiling. More specifically, the travel rails 2 are hung from the ceiling. In other words, the transport vehicles 3 are ceiling-hung transport vehicles. Each of the articles 7 transported by the transport vehicles 3 may be, for example, a front-opening unified pod (FOUP) containing semiconductor substrates, but is not limited to this example. In the example in FIGS. 2 and 5, the processing devices 10 perform predetermined processing on objects (semiconductor substrates in this example) contained in the articles 7.

The transport vehicles 3 herein are ceiling-hung transport vehicles as an example. However, each transport vehicle 3 may be, for example, an article transport vehicle that travels on the ground (including an article transport vehicle that travels along compartments of a storage shelf having multiple compartments arranged vertically) or a travel cart of a stacker crane. The transport vehicles 3 may be in any form that operates with electric power from the feed lines 51. The transport vehicles 3 are not limited to article transport vehicles.

A direction along the travel path 1 is hereafter referred to as a travel direction X, and a direction orthogonal to the travel direction X as viewed in the vertical direction as a width direction Y.

As shown in FIGS. 1 and 3 to 5, each transport vehicle 3 includes a transporter 31 operable to transport the articles 7. In the present embodiment, the transporter 31 includes a traveler 30 that travels along the travel path 1. The transporter 31 also includes a holder 33 for holding an article 7 and a mover 5 for moving the holder 33 to transfer the article 7 to and from the transfer area 10a.

As shown in FIGS. 3 to 5, the traveler 30 includes drive wheels 30a, a drive 30b for driving the drive wheels 30a, and a rotation position detector 29 that detects the positions of the drive wheels 30a in the rotation direction. In this example, the traveler 30 includes the multiple drive wheels 30a. These drive wheels 30a are driven by the drive 30b (including an electric motor and a power transmission from the electric motor to the drive wheels 30a in this example) to rotate on the travel rails 2. In this example, the travel rails 2 are a pair of rails separated in the width direction Y The multiple drive wheels 30a (a pair of drive wheels 30a in this example) rotate on the respective travel rails 2. The traveler 30 also includes multiple guide wheels 30c. The guide wheels 30c rotate on side surfaces of the travel rails 2 disposed inward in the width direction Y.

As shown in FIG. 3, the holder 33 suspends the article 7. The holder 33 includes a pair of holding tabs 33a. The pair of holding tabs 33a are separated in the travel direction X. The holder 33 also includes an electric holder drive motor (not shown) that moves the pair of holding tabs 33a closer to and away from each other. The pair of holding tabs 33a can change the posture between a holding posture in which the pair of holding tabs 33a move closer to each other in the travel direction X and hold the article 7 and a releasing posture in which the pair of holding tabs 33a move away from each other in the travel direction X and release the article 7. The article 7 includes a body 71 containing an object and a flange 72 disposed above the body 71. The pair of holding tabs 33a hold the flange 72.

As shown in FIGS. 3 to 5, the mover 5 is suspended from the traveler 30.

The mover 5 is disposed below the travel rails 2. In the present embodiment, the mover 5 moves the holder 33 to a reference position T1 when the transport vehicle 3 travels and to a transfer position T2 when the article 7 is transferred to and from the transfer areas 10a. In this example, each transport vehicle 3 includes, as the mover 5, a lifter 34 that raises and lowers the holder 33, a slider 36 that slides the holder 33 in the horizontal direction, and a rotator 37 that rotates the holder 33 about an axis extending in the vertical direction.

The lifter 34 includes a drum, a belt wound around the drum with a distal end connected to the holder 33, and a lifter motor that rotates the drum and drives the belt. The lifter 34 raises and lowers the holder 33 by driving the lifter motor and rotating the drum.

For example, as shown in FIGS. 2 and 5, the lifter 34 can raise and lower the holder 33 between the reference position T1 and the transfer position T2 when the transfer areas 10a (the load ports for the processing devices 10 in this example) are arranged directly below the travel rails 2.

The slider 36 slides the holder 33 in the width direction Y. The slider 36 includes a slider assembly that moves the holder 33 in the width direction Y and a slider motor that drives the slider assembly. For example, the slider 36 slides the holder 33 between the reference position T1 and a position farther in the width direction Y than the reference position T1 when the transfer areas 10a are arranged at positions spaced from the travel rails 2 in the width direction Y. In this example, the reference position T1 is set above the transfer position T2.

The rotator 37 includes a rotator assembly that rotates the holder 33 and the lifter 34 and a rotator motor that drives the rotator assembly. For example, the rotator 37 integrally rotates the holder 33 and the lifter 34 to change the orientation of the article 7 held by the holder 33 as appropriate for transferring when the orientation of the article 7 held by the holder 33 at the reference position T1 and the orientation of the article 7 placed on the transfer area 10a are different from each other.

In the present embodiment, each transport vehicle 3 includes a container case 32. The container case 32 is hung from the traveler 30 and disposed below the travel rails 2. The container case 32 accommodates the holder 33 at the reference position T1 and the article 7 held by the holder 33. The container case 32 also accommodates the mover 5 (the lifter 34, the slider 36, and the rotator 37). The container case 32 covers the article 7 held by the holder 33 at the reference position T1 from both sides in the travel direction X and from above.

In the present embodiment, as shown in FIGS. 1 and 3, the transporter 31 includes an obstacle detector 38 that detects an obstacle on the travel path 1 on which the transport vehicles 3 travel. The obstacle detector 38 (an optical sensor in this example) creates a detection area E to detect an obstacle located frontward in the travel direction X of the corresponding transport vehicle 3. This allows the transport vehicle 3 to avoid colliding with the obstacle during traveling. In this example, as shown in FIG. 10, the size of the detection area E in the width direction Y is larger than the size of the transport vehicle 3 in the width direction Y. The detection area E may have a different shape or size as appropriate for, for example, the size of the facility. In the example in FIG. 3, the obstacle detector 38 is disposed on the container case 32. The obstacle detector 38 is not limited to an optical sensor and may be, for example, a camera sensor. As shown in FIGS. 1, 3, and 4, the transporter 31 includes a detector 28 that detects the detectable members T. In this example, the detectable members T are one-dimensional codes or two-dimensional codes, and the detector 28 is a reader that can read these codes (FIG. 4).

Various actuators included in the transport vehicles 3 receive electric power supplied from the feed lines 51 through a power receiving device 35 included in each transport vehicle 3 (FIG. 1). In this example, the feed lines 51 are respectively arranged on the pair of travel rails 2. More specifically, a pair of feed lines 51 are arranged across the power receiving device 35. When a high-frequency current flows through the feed lines 51, the power receiving device 35 generates a magnetic field around the feed lines 51. The power receiving device 35 includes, for example, a pickup coil and a magnetic core. The pickup coil is induced by electromagnetic induction from the magnetic field. The induced AC electric power is converted to direct current by a rectifier circuit such as a full-wave rectifier circuit or a power receiving circuit including, for example, a smoothing capacitor, and is supplied to the actuators and drive circuits.

As shown in FIG. 1, each transport vehicle 3 further includes a power storage 41 that temporarily stores electric power. The power storage 41 supplies electric power to the second controller H2, the transporter 31, the obstacle detector 38, and the detector 28 for a predetermined period when electric power supply from the AC power supply 52 to the transport vehicles 3 is interrupted.

As described above, the second controller H2 is included in each transport vehicle 3 (FIG. 1). The second controller H2 controls, for example, the traveler 30, the holder 33, the mover 5, the detector 28, the obstacle detector 38, and the power receiving device 35. The second controller H2 can communicate with the first controller H1. In this example, the second controller H2 can also communicate with an operation terminal 8. The operation terminal 8 is an external terminal for operating the transport vehicles 3 and is operated by a manager of the transport facility 100 (including an operator who performs an operation at the transport facility 100). The operation terminal 8 is a handheld terminal in this example, but is not limited to this example.

In addition to controlling the travel of the multiple transport vehicles 3, the first controller H1 has the function to control the entire transport facility 100 (e.g., the AC power supply 52) and is disposed in the facility. The first controller H1 includes an obtainer 112 that obtains information from the multiple transport vehicles 3, a storage 111 that stores the obtained information, and a determiner 113 that performs determination based on the obtained information. In this example, the first controller H1 can communicate with the second controllers H2 mounted on the respective transport vehicles 3 as described above, and can also communicate with the operation terminal 8.

Each of the first controller H1 and the second controllers H2 includes, for example, a processor such as a microcomputer and peripheral circuitry including a memory. The functions of the components are implemented by the above hardware and a program executable on a processor such as a computer operating in cooperation with each other.

The control system H can switch the mode of each of the transport vehicle 3 between an automatic mode in which the corresponding traveler 30 travels to a set destination and stops traveling while the obstacle detector 38 is detecting an obstacle and a manual mode in which the traveler 30 travels based on a command from the operation terminal 8 operated by the manager. In this example, the second controller H2 switches the traveler 30 between the automatic mode and the manual mode based on a command from the first controller H1.

In the automatic mode, when receiving a transport command from the first controller H1, the second controller H2 controls the traveler 30 to transport the article 7 to a transfer area 10a that is a transport destination. More specifically, the second controller H2 causes the transport vehicle 3 to travel along the travel path 1 and stop at a position corresponding to the transfer area 10a. The second controller H2 controls the holder 33 and the lifter 34 to transfer the article 7 held by the holder 33 to the transfer area 10a. The second controller H2 may control, based on the position of the transfer area 10a, the slider 36 or the rotator 37 to transfer the article 7. When the obstacle detector 38 detects an obstacle during traveling, the second controller H2 controls the traveler 30 to stop the transport vehicle 3 at a position in front of the obstacle.

In the manual mode, the second controller H2 controls the transport vehicle 3 based on a command received from the operation terminal 8. For example, in response to an operation on the operation terminal 8 by the manager, the second controller H2 causes the transport vehicle 3 to travel to a maintenance zone (not shown). Similarly, in response to an operation on the operation terminal 8 by the manager, the second controller H2 may cause the holder 33 to move or the pair of holding tabs 33a to change the posture.

The control system H obtains operating state information indicating the operating state of each transporter 31. In the present embodiment, the first controller H1 obtains the operating state information of each transport vehicle 3 from the corresponding second controller H2. In the present embodiment, the operating state information includes holder position information indicating the position of the holder 33, travel mode information indicating the mode of the transport vehicle 3, obstacle detection information indicating the detection state of the obstacle detector 38, and traveling position information indicating the position of the transport vehicle 3 on the travel path 1. In this example, the control system H obtains the operating state information at every predetermined period (e.g., every second).

The holder position information includes information indicating whether the holder 33 is at the reference position T1, information indicating whether the pair of holding tabs 33a are in the holding posture or in the releasing posture, and information indicating whether the pair of holding tabs 33a are holding the article 7. The holder position information also includes information indicating the position of the holder 33 in the vertical direction and in the lateral direction (the width direction Y in this example). The transporter 31 may thus include a sensor that detects, for example, the position of the holder 33 described above. The travel mode information includes information indicating whether the transport vehicle 3 is in the automatic mode or in the manual mode. The obstacle detection information includes information indicating whether the obstacle detector 38 is detecting an obstacle. The traveling position information includes the address information included in the detectable member T detected by the detector 28 and a detection result from the rotation position detector 29. In this example, the rotation position detector 29 is an encoder that detects the rotation amount (rotation angle) of the drive wheels 30a relative to a reference position (the position of the detectable member T in this example). The position of the transport vehicle 3 can be identified based on, for example, the address information of the detectable member T detected most recently and the rotation amount (rotation angle) of the drive wheels 30a relative to the detectable member T. The obtainer 112 in the first controller H1 obtains, for example, the holder position information, the travel mode information, the obstacle detection information, and the traveling position information from each transport vehicle 3 on the travel path 1 and stores these pieces of information into the storage 111 as the operating state information (FIG. 1).

When the external electric power supply (in other words, the electric power supply from the utility power supply to the power receiver 4) is interrupted due to, for example, a power outage, the electric power supply from the AC power supply 52 to the transport vehicles 3 is also interrupted. Each transport vehicle 3 on the travel path 1 thus loses a driving force for traveling and stops. When the electric power supply from the utility power supply to the power receiver 4 is restored and the AC power supply 52 resumes transmitting electric power to each transport vehicle 3, the transport vehicle 3 obtains a driving force for resuming traveling. In this example, the restoration operation may be largely shortened when the control system H collectively causes the multiple transport vehicles 3 to resume traveling based on the operating state information of each transport vehicle 3, compared with when the manager manually (e.g., by operating the operation terminal 8) causes each transport vehicle 3 to resume traveling. The electric power supply from the AC power supply 52 to the transport vehicles 3 may be interrupted as described above, or may be interrupted due to a failure in the AC power supply 52 or when the AC power supply 52 is temporarily turned off (powered off) for some reason.

However, some transport vehicles 3 are to resume traveling in response to a manual operation by the manager, rather than through the control by the control system H. For example, when a transport vehicle 3 during a transfer operation or a transport vehicle 3 indicating an abnormality resumes traveling together with other transport vehicles 3, another abnormality or issue may occur. Thus, the control system H may not cause such transport vehicles 3 to resume traveling.

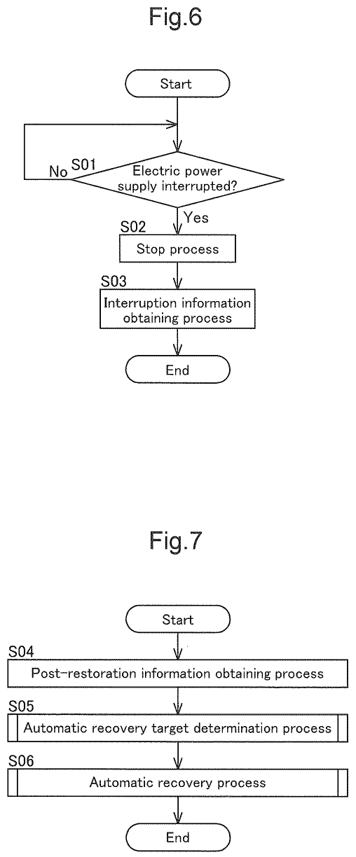

As shown in FIGS. 6 to 9, the control system H performs an interruption information obtaining process, a post-restoration information obtaining process, an automatic recovery target determination process, and an automatic recovery process. Each of the processes will be described in detail below. In the present embodiment, when the electric power supply from the power receiver 4 is interrupted, the first controller H1 receives electric power from the uninterruptible power supply 53 that is a backup electric power supply for a predetermined period. The first controller H1 receiving electric power from the uninterruptible power supply 53 controls the entire facility including the transport vehicles 3. Each second controller H2 receives electric power from the power storage 41 (a capacitor in this example) in the corresponding transport vehicle 3 and controls the transport vehicle 3.

The interruption information obtaining process is a process of obtaining, when the electric power supply to the transport vehicles 3 is interrupted, the operating state information of each transport vehicle 3 as preliminary operating state information and storing the obtained preliminary operating state information within a period after the electric power supply is interrupted and before the transporter 31 stops operating. As shown in FIG. 6, when the electric power supply from the power receiver 4 is interrupted (Yes in S01), the first controller H1 performs a stop process to cause the multiple transport vehicles 3 to stop traveling (S02). Each second controller H2 receives a stop command from the first controller H1 and controls the corresponding traveler 30 to start decelerating. When the electric power supply is interrupted, the control system H (the second controller H2 in this example) controls the drive 30b to stop the drive wheels 30a before the drive 30b stop operating. When the drive wheels 30a stop, or in other words, when the transport vehicle 3 stops, the control system H performs the interruption information obtaining process (S03). The first controller H1 instructs each second controller H2 mounted in the corresponding transport vehicle 3 to transmit the operating state information (preliminary operating state information) of the transport vehicle 3. The second controller H2 transmits, to the first controller H1, the operating state information obtained from the transporter 31 as the preliminary operating state information. In this example, each second controller H2 obtains the operating state information after the corresponding transport vehicle 3 stops, and transmits the operating state information to the first controller H1. In this example, the transport vehicle 3 is powered off before the electric power in the power storage 41 is completely consumed. The timing for the second controller H2 to obtain and transmit the preliminary operating state information of the corresponding transport vehicle 3 may be changed as appropriate. For example, the control system H may perform the interruption information obtaining process immediately before causing the drive wheels 30a of the transport vehicle 3 to stop. In this case, the second controller H2 may transmit, to the first controller H1, the operating state information obtained immediately before the corresponding transport vehicle 3 stops as the preliminary operating state information. The above timing may be changed when, for example, the second controller H2 cannot obtain or transmit the preliminary operating state information of the corresponding transport vehicle 3 for some reason after the drive wheels 30a stop.

The post-restoration information obtaining process is a process of obtaining, after the electric power supply is restored, the operating state information of each transport vehicle 3 as the post-restoration operating state information. In the present embodiment, when the electric power supply from the power receiver 4 is restored, the first controller H1 instructs the second controllers H2 to transmit the operating state information of the respective transport vehicles 3 as the post-restoration operating state information. More specifically, when the electric power supply from the power receiver 4 is restored, the first controller H1 activates the multiple transport vehicles 3 to be in a state in which the transport vehicles 3 can communicate with the respective second controllers H2. When a predetermined period passes after the activation of the transport vehicles 3, the first controller H1 instructs the second controllers H2 to transmit the operating state information as the post-restoration operating state information. The first controller H1 stores the obtained post-restoration operating state information into the storage 111. The first controller H1 may instruct the second controllers H2 to transmit the operating state information of the respective transport vehicles 3 immediately after the activation as the post-restoration operating state information.

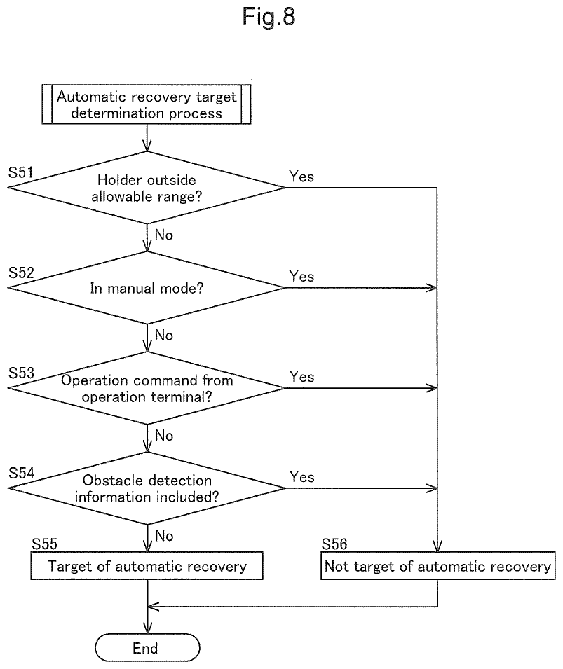

As shown in FIG. 8, the automatic recovery target determination process is a process of determining whether each of the multiple transport vehicles 3 is a target of the automatic recovery based on the result of comparison between the preliminary operating state information and the post-restoration operating state information. The control system H (the determiner 113 in the first controller H1 in this example) compares, for each of the transport vehicles 3, the preliminary operating state information stored in the storage 111 and the newly obtained post-restoration operating state information. In this example, each of the second controllers H2 in the transport vehicles 3 can also compare, after the electric power supply is restored, the preliminary operating state information and the post-restoration operating state information of the corresponding transport vehicle 3. In this case, the second controller H2 obtains the preliminary operating state information of the transport vehicle 3 from the first controller H1.

In the automatic recovery target determination process, when at least one of the preliminary operating state information or the post-restoration operating state information includes the holder position information indicating that the holder 33 is located outside a predetermined allowable range including the reference position T1, the control system H determines that the transport vehicle 3 is not a target of the automatic recovery. In this example, when at least one of the preliminary operating state information or the post-restoration operating state information includes the holder position information (Yes in S51) indicating that the holder 33 is located outside the allowable range including the reference position T1 (indicating that the holder 33 is located outside the allowable range including the reference position T1 in the lateral direction, or in the width direction Y, and in the vertical direction in this example), the first controller H1 determines that the transport vehicle 3 is not a target of the automatic recovery (S56). In contrast, when both the preliminary operating state information and the post-restoration operating state information include, as the holder position information, information indicating that the holder 33 is located within the allowable range including the reference position T1, the first controller H1 may determine that the transport vehicle 3 is a target of the automatic recovery. In some embodiments, when the post-restoration operating state information includes, as the holder position information, information indicating that the holder 33 is located within the allowable range including the reference position T1, the first controller H1 may determine that the transport vehicle 3 is a target of the automatic recovery independently of the holder position information included in the preliminary operating state information.

In the automatic recovery target determination process, when at least one of the preliminary operating state information or the post-restoration operating state information includes the travel mode information indicating that the transport vehicle 3 is in the manual mode, the control system H also determines that the transport vehicle 3 is not a target of the automatic recovery. When at least one of the preliminary operating state information or the post-restoration operating state information includes the travel mode information indicating that the transport vehicle 3 in the manual mode (Yes in S52), the first controller H1 determines that the transport vehicle 3 is not a target of the automatic recovery (S56). In contrast, when both the preliminary operating state information and the post-restoration operating state information include the travel mode information indicating that the transport vehicle 3 is in the automatic mode, the first controller H1 may determine that the transport vehicle 3 is a target of the automatic recovery. In some embodiments, when the post-restoration operating state information includes the travel mode information indicating that the transport vehicle 3 is in the automatic mode, the first controller H1 may determine that the transport vehicle 3 is a target of the automatic recovery independently of the travel mode information included in the preliminary operating state information.

In the automatic recovery target determination process, when at least one of the preliminary operating state information or the post-restoration operating state information includes operation command information indicating that an operation command has been received from the operation terminal 8, the control system H determines that the transport vehicle 3 is not a target of the automatic recovery. When at least one of the preliminary operating state information or the post-restoration operating state information includes the operation command information indicating that an operation command has been received from the operation terminal 8 (Yes in S53), the first controller H1 determines that the transport vehicle 3 is not a target of the automatic recovery (S56). In contrast, when none of the preliminary operating state information and the post-restoration operating state information includes the operation command information indicating that an operation command has been received from the operation terminal 8, the first controller H1 may determine that the transport vehicle 3 is a target of the automatic recovery. In some embodiments, when the post-restoration operating state information includes no operation command information indicating that an operation command has been received from the operation terminal 8, the first controller H1 may determine that the transport vehicle 3 is a target of the automatic recovery independently of whether the preliminary operating state information includes the operation command information indicating that an operation command has been received from the operation terminal 8.

In this example, when the post-restoration operating state information includes the operation command information indicating that an operation command has been received from the operation terminal 8 (and, in this example, also includes information indicating that the transport vehicle 3 has actually moved based on the operation command) as well, the first controller H1 may determine that the transport vehicle 3 is a target of the automatic recovery. For example, the traveling position information included in the preliminary operating state information is referred to as preliminary traveling position information, and the raveling position information included in the post-restoration operating state information as post-restoration traveling position information. In the automatic recovery target determination process, when the difference (the positional difference in the travel direction X in this example) between a position indicated by the preliminary traveling position information and a position indicated by the post-restoration traveling position information is greater than or equal to a predetermined determination threshold, the control system H may determine that the transport vehicle 3 is not a target of the automatic recovery. In other words, when the difference between the position indicated by the preliminary traveling position information and the position indicated by the post-restoration traveling position information is less than the determination threshold, the control system H may determine that the transport vehicle 3 is a target of the automatic recovery. More specifically, the first controller H1 activates the multiple transport vehicles 3 after the electric power supply is restored. Subsequently, when the manager operates the operation terminal 8 to move any of the transport vehicles 3 in a predetermined period, the corresponding second controller H2 transmits, to the first controller H1, the position of the moved transport vehicle 3 as the post-restoration traveling position information. When the amount of movement of the transport vehicle 3 in response to the operation by the manager is greater than or equal to the determination threshold, the first controller H1 may determine that the transport vehicle 3 is not a target of the automatic recovery. The determination threshold may be set based on, for example, the distance between a detectable member T detected before the electric power supply is restored and another detectable member T disposed frontward in the travel direction X from the detected detectable member T. When the difference between the position indicated by the preliminary traveling position information and the position indicated by the post-restoration traveling position information is greater than or equal to the determination threshold as well, the control system H may determine that the transport vehicle 3 is a target of the automatic recovery. When no post-restoration traveling position information is obtained for some reason as well, the control system H may determine that the transport vehicle 3 is a target of the automatic recovery. In this case, the control system H may obtain the post-restoration traveling position information by causing the transport vehicle 3 to travel at a low speed to the detectable member T disposed frontward in the travel direction and closest to the transport vehicle 3.

In the automatic recovery target determination process, when at least one of the preliminary operating state information or the post-restoration operating state information includes the obstacle detection information indicating that an obstacle is being detected, the control system H determines that the transport vehicle 3 is not a target of the automatic recovery. When at least one of the preliminary operating state information or the post-restoration operating state information includes the obstacle detection information indicating that an obstacle is being detected (Yes in S54), the first controller H1 determines that the transport vehicle 3 is not a target of the automatic recovery. In contrast, when none of the preliminary operating state information and the post-restoration operating state information includes the obstacle detection information indicating that an obstacle is being detected, the first controller H1 may determine that the transport vehicle 3 is a target of the automatic recovery. In some embodiments, when the preliminary operating state information includes the obstacle detection information indicating that an obstacle is being detected, but the post-restoration operating state information includes no obstacle detection information indicating that an obstacle is being detected, the first controller H1 may determine that the transport vehicle 3 is a target of the automatic recovery.

In this example, as shown in FIG. 8, when none of the preliminary operating state information and the post-restoration operating state information includes the holder position information indicating that the holder 33 is not at the reference position T1 (No in S51), the travel mode information indicating that the transport vehicle 3 is in the manual mode (No in S52), the information indicating that an operation command has been received from the operation terminal 8 (No in S53), or the obstacle detection information indicating that an obstacle is being detected (No in S54), the first controller H1 determines that the transport vehicle 3 is a target of the automatic recovery (S55).

The automatic recovery process is a process of controlling the transport vehicle 3 determined to be a target of the automatic recovery through the automatic recovery target determination process and causing the transport vehicle 3 to resume operating in the same manner as before the electric power supply is interrupted. In the present embodiment, each transport vehicle 3 determined to be a target of the automatic recovery through the automatic recovery target determination process is referred to as a target transport vehicle 3A. In the automatic recovery process, the control system H transmits, to each target transport vehicle 3A, a reconstruction command to reconstruct the preliminary operating state information (S61). The first controller H1 transmits, in the reconstruction command, the preliminary operating state information stored in the storage 111 to the second controller H2 in the target transport vehicle 3A. The target transport vehicle 3A can thus determine (reconstruct) the position at which the target transport vehicle 3A stopped automatically before the electric power supply is restored (in other words, the address information of the detectable member T detected most recently and the rotation amount of the drive wheels 30a) and the holding state of an article 7 (whether an article 7 is held). The second controller H2 transmits, to the first controller H1, a response indicating that the preliminary operating state information has been reconstructed. For the target transport vehicle 3A transmitting no response to the reconstruction command, the first controller H1 identifies the target transport vehicle 3A as having an abnormality and excludes the target transport vehicle 3A from the automatic recovery.

In this example, each second controller H2 can compare the preliminary operating state information and the post-restoration operating state information of the corresponding transport vehicle 3 after the electric power supply is restored. When the result of the comparison corresponds to the result of the determination for the transport vehicle 3 performed by the first controller H1 (the determiner 113 in this example) in the automatic recovery target determination process, the second controller H2 can transmit, to the first controller H1, permission information indicating the correspondence between these results. The first controller H1 can perform the automatic recovery process on the transport vehicle 3 from which the permission information has been received. The first controller H1 can exclude, from the automatic recovery process, the transport vehicle 3 from which no permission information has been received.

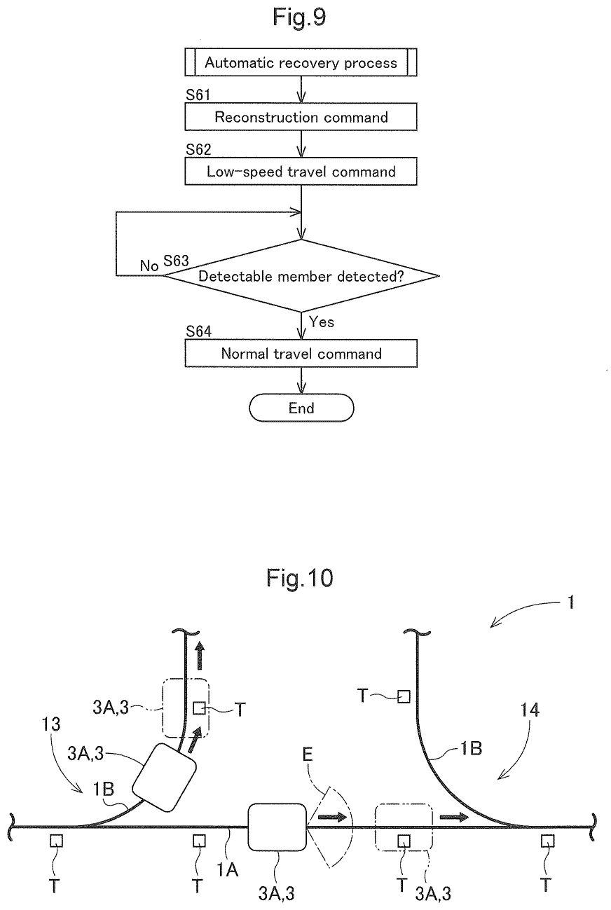

The control system H causes the target transport vehicle 3A with the reconstructed preliminary operating state information to start traveling, and controls the traveling target transport vehicle 3A to travel at a speed lower than a normal speed of traveling without interruption of the electric power supply until the target transport vehicle 3A detects a first detectable member T. The normal speed of traveling is a speed at which a transport vehicle 3 transporting an article 7 travels on the straight section 1A or on the curved section 1. As shown in FIGS. 9 and 10, the first controller H1 transmits, to the second controller H2 in each target transport vehicle 3A with the reconstructed preliminary operating state information (indicated by a solid line in FIG. 10), a low-speed travel command to cause the target transport vehicle 3A to start traveling at a speed lower than the normal speed of traveling (S62). The second controller H2 controls the traveler 30 to cause the target transport vehicle 3A to travel at a low speed. When a detectable member T (indicated by a two-dot-dash line in FIG. 10) is detected frontward in the travel direction (Yes in S63), the second controller H2 transmits detection information to the first controller H1. When receiving the detection information, the first controller H1 transmits a normal travel command to the second controller H2 (S64). The normal travel command is a command to control the target transport vehicle 3A to travel at the normal speed of traveling. In some embodiments, the first controller H1 may transmit the normal travel command to the second controller H2 in each target transport vehicle 3A when the ratio of the target transport vehicles 3A that have detected a detectable member T is greater than or equal to a predetermined threshold. In this case, the target transport vehicles 3A that have detected a detectable member T are controlled to travel at a low speed until the ratio of the target transport vehicles 3A that have detected a detectable members T reaches the above threshold. Each target transport vehicle 3A traveling at the normal speed of traveling resumes transporting an article 7 based on order information. The order information may be included in the preliminary operating state information, or may be transmitted from the first controller H1 to the second controller H2 after the preliminary operating state information is reconstructed. When the target transport vehicle 3A traveling at a low speed detects an obstacle, the first controller H1 may exclude the target transport vehicle 3A from the automatic recovery.

### Second Embodiment

A transport facility according to a second embodiment will now be described with reference to the drawings. The transport facility according to the present embodiment will be described below focusing on its differences from the transport facility according to the first embodiment. The components not described in the embodiment are the same as those in the first embodiment, and denoted with the same reference signs and will not be described in detail.

In the present embodiment, each second controller H2 includes a voltage monitor (not shown) that monitors a voltage applied to the drive 30b. When the voltage applied to the drive 30b is lower than a preset setting voltage, the second controller H2 controls the drive 30b to decelerate and stop the traveler 30. The setting voltage is greater than a lower limit voltage that allows the transport vehicles 3 to travel.

Subsequently, the control system H (the second controller H2 in this example) identifies the stop position of the drive wheels 30a based on the detection result from the detector 28 and the detection result from the rotation position detector 29 and stores, as the preliminary traveling position information, the identified stop position of the drive wheels 30a and the detection result from the rotation position detector 29. The stop position of the drive wheels 30a may be identified based on the position (address information) of the detectable member T detected most recently and the detection result (the rotation amount, or a rotation angle, of the drive wheels 30a relative to the detectable member T in this example) from the rotation position detector 29. In this example, an absolute encoder is used as the rotation position detector 29. The second controller H2 stores the stop position of the drive wheels 30a and the rotation amount of the drive wheels 30a relative to the detectable member T detected most recently into a nonvolatile memory (not shown). The stop position of the drive wheels 30a included in the preliminary traveling position information may be the stop position or an indicator (more specifically, the detection result from the detector 28 and the detection result from the rotation position detector 29) that can identify the stop position.

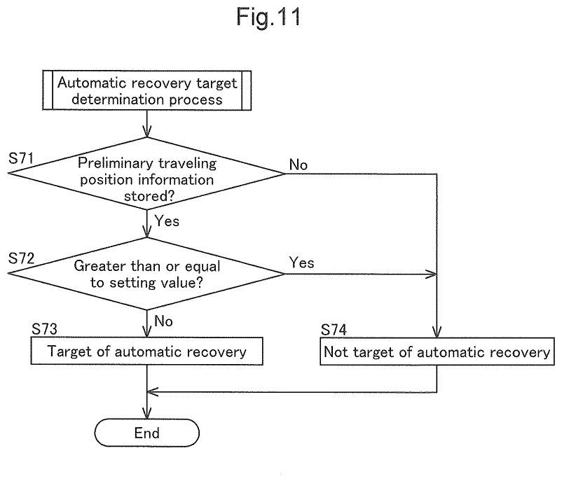

After the electric power supply is restored, the control system H (the second controller H2 in this example) with the preliminary traveling position information stored obtains the detection result from the rotation position detector 29 as the post-restoration traveling position information. In the automatic recovery target determination process, when the difference between the detection results from the rotation position detector 29 included in the preliminary traveling position information and in the post-restoration traveling position information is greater than or equal to a predetermined setting value, the control system H determines that the transport vehicle 3 is not a target of the automatic recovery. In this example, as shown in FIG. 11, when the nonvolatile memory in the second controller H2 stores no preliminary traveling position information (No in S71), the second controller H2 determines that the transport vehicle 3 is not a target of the automatic recovery (S74). When the nonvolatile memory stores the preliminary traveling position information (Yes in S71), the second controller H2 obtains, as the post-restoration traveling position information, the detection result from the rotation position detector 29 (the rotation amount of the drive wheels 30a) after the electric power supply is restored. In this example, an absolute encoder is used as the rotation position detector 29 as described above. Thus, when the drive wheels 30a rotate for some reason during the interruption of the electric power supply, for example, the rotation amount of the drive wheels 30a can be detected after the electric power supply is restored. When the difference between the rotation amounts of the drive wheels 30a included in the preliminary traveling position information and in the post-restoration traveling position information is greater than or equal to a predetermined setting value (Yes in S72), the second controller H2 determines that the transport vehicle 3 is not a target of the automatic recovery (S74). When the difference between these rotation amounts is less than the setting value (No in S72), the second controller H2 determines that the transport vehicle 3 is a target of the automatic recovery (S73). The second controller H2 transmits error information to the first controller H1 when the transport vehicle 3 is not a target of the automatic recovery. The setting value may be set to, for example, 600 (⅙ rotation) as the difference between the rotation amounts. In other words, when the difference between the rotation amounts is 600 or greater, the drive wheels 30a may be determined to have been moved manually, and the transport vehicle 3 may be excluded from the automatic recovery. The setting value may be changed as appropriate. In other words, the setting value may be changed to, for example, 30, 90, or 120°. To obtain the preliminary traveling position information or the post-restoration traveling position information, devices other than the rotation position detector 29 (e.g., magnetic tape extending along the travel rails 2 and a reader that reads the magnetic tape) may be used.

For each transport vehicle 3 determined to be a target of the automatic recovery through the automatic recovery target determination process, the control system H determines the stop position of the drive wheels 30a after the electric power supply is restored based on the stop position of the drive wheels 30a included in the preliminary traveling position information and the difference between the detection results from the rotation position detector 29 included in the preliminary traveling position information and in the post-restoration traveling position information. The stop position of the drive wheels 30a after the electric power supply is restored is determined based on the position information (address information) of the detectable member T detected most recently included in the preliminary traveling position information, the rotation amount of the drive wheels 30a, and a difference of the rotation amount of the drive wheels 30a included in the post-restoration traveling position information from the rotation amount of the drive wheels 30a included in the preliminary traveling position information (in other words, the difference between the two rotation amounts). When identifying the stop position of the drive wheels 30a after the electric power supply is restored, the second controller H2 transmits, to the first controller H1, the stop position as the traveling position information. When receiving the traveling position information, the first controller H1 instructs the second controller H2 to resume transporting the article 7.

### Other Embodiments

A transport facility according to other embodiments will now be described.

(1) In the first embodiment described above, each of the multiple transport vehicles 3 includes the power storage 41. When the electric power supply is interrupted, the second controller H2 uses electric power from the power storage 41 to control the traveler 30. However, the structure is not limited to this example. For example, when the electric power supply to the transport vehicle 3 is interrupted, the second controller H2 may use electric power supplied from the uninterruptible power supply 53 to control the traveler 30. More specifically, when the electric power supply is interrupted, the AC power supply 52 may supply electric power received from the uninterruptible power supply 53 to the second controller H2. In some embodiments, the second controller H2 may use electric power from regenerative brakes on the drive wheels 30a.

(2) In the first embodiment described above, the control system H determines that the transport vehicle 3 is not a target of the automatic recovery when at least one of the preliminary operating state information or the post-restoration operating state information includes the holder position information indicating that the holder 33 is not at the reference position T1. However, the structure is not limited to this example. For example, the control system H may determine that the transport vehicle 3 is not a target of the automatic recovery when at least one of the preliminary operating state information or the post-restoration operating state information includes the holder position information indicating that the holder 33 is located outside a range of the container case 32 including the reference position T1. As described above, the predetermined allowable range including the reference position T1 may be set inside the container case 32. The above allowable range may be set as a range within a predetermined distance in the width direction Y and a predetermined distance in the vertical direction with respect to the reference position T1.

(3) In the first embodiment described above, the control system H determines that the transport vehicle 3 is not a target of the automatic recovery when at least one of the preliminary operating state information or the post-restoration operating state information includes the travel mode information indicating that the transport vehicle 3 is in the manual mode. However, the structure is not limited to this example. The control system H may determine that the transport vehicle 3 is a target of the automatic recovery when both the preliminary operating state information and the post-restoration operating state information include the travel mode information indicating that the transport vehicle 3 is in the manual mode.

(4) In the first embodiment described above, the control system H determines that the transport vehicle 3 is not a target of the automatic recovery when at least one of the preliminary operating state information or the post-restoration operating state information includes the obstacle detection information indicating that an obstacle is being detected. However, the structure is not limited to this example. With at least one of the preliminary operating state information or the post-restoration operating state information including the obstacle detection information indicating that an obstacle is being detected, the control system H may determine that the transport vehicle 3 is a target of the automatic recovery when the detected obstacle is unlikely to interfere with the transport vehicle 3 during traveling. For example, with the transport vehicle 3 having the post-restoration operating state information including the obstacle detection information, the control system H may determine that the transport vehicle 3 is a target of the automatic recovery. In this case, the automatic recovery process may be performed on the transport vehicle 3 after information indicating that no obstacle is being detected is obtained as operation information.

(5) In the first embodiment described above, the control system H determines that the transport vehicle 3 is not a target of the automatic recovery in the automatic recovery target determination process when the difference between the position indicated by the preliminary traveling position information and the position indicated by the post-restoration traveling position information is greater than or equal to a predetermined determination threshold. However, the structure is not limited to this example. For example, the control system H may not determine whether the transport vehicle 3 is a target of the automatic recovery based on the difference between the position indicated by the preliminary traveling position information and the position indicated by the post-restoration traveling position information.

(6) In the second embodiment described above, the second controller H2 determines that the transport vehicle 3 is not a target of the automatic recovery in the automatic recovery target determination process when the difference between the detection results from the rotation position detector 29 included in the preliminary traveling position information and in the post-restoration traveling position information is greater than or equal to a predetermined setting value. However, the structure is not limited to this example. For example, the first controller H1 may perform the automatic recovery target determination process described above.

(7) In the first embodiment described above, the control system H causes the target transport vehicle 3A with the reconstructed preliminary operating state information to start traveling, and controls the traveling target transport vehicle 3A to travel at a speed lower than the normal speed of traveling without interruption of the electric power supply until the target transport vehicle 3A detects a first detectable member T. However, the structure is not limited to this example. The control system H may cause the target transport vehicle 3A to continue traveling at a speed lower than the normal speed of traveling without interruption of the electric power supply for a predetermined period after the target transport vehicle 3A has detected a first detectable member T. The control system H may not cause the target transport vehicle 3A to travel at a low speed when the target transport vehicle 3A traveling at the normal speed is sufficiently spaced from and is unlikely to collide with other transport vehicles 3.

(8) The structure described in each of the above embodiments may be combined with any other structures described in the other embodiments unless any contradiction arises. For other structures as well, the embodiments described herein are merely illustrative in all aspects and may be modified as appropriate without departing from the spirit and scope of the disclosure.

### Overview of Embodiments

An overview of the transport facility described above is provided below.

A transport facility according to an aspect of the disclosure includes a plurality of transport vehicles that transport articles, a control system that controls the plurality of transport vehicles, and a power feeder that supplies electric power to the plurality of transport vehicles and the control system. Each of the plurality of transport vehicles includes a transporter operable to transport the articles. The control system obtains operating state information indicating an operating state of the transporter in each of the plurality of transport vehicles. The control system performs an interruption information obtaining process, a post-restoration information obtaining process, an automatic recovery target determination process, and an automatic recovery process. The interruption information obtaining process is a process of obtaining, in response to electric power supply to the plurality of transport vehicles being interrupted, the operating state information of each of the plurality of transport vehicles as preliminary operating state information and storing the obtained preliminary operating state information within a period after the electric power supply is interrupted and before the transporter stops operating. The post-restoration information obtaining process is a process of obtaining, after the electric power supply is restored, the operating state information of each of the plurality of transport vehicles as post-restoration operating state information. The automatic recovery target determination process is a process of determining whether each of the plurality of transport vehicles is a target of automatic recovery based on a result of comparison between the preliminary operating state information and the post-restoration operating state information. The automatic recovery process is a process of controlling, among the plurality of transport vehicles, a transport vehicle determined to be the target of the automatic recovery through the automatic recovery target determination process, and causing the transport vehicle to resume operating in a same manner as before the electric power supply is interrupted.

This structure can determine whether each of the plurality of transport vehicles is a target of the automatic recovery when the electric power supply to the transport vehicles is interrupted due to, for example, a power outage and then restored. The automatic recovery process can thus be simply performed on transport vehicles in a state appropriate for the automatic recovery and not on transport vehicles in a state inappropriate for the automatic recovery.

This can reduce the workload of an operator compared with when the operator manually performs the recovery process on all transport vehicles, and can also reduce the likelihood of additional abnormality or issues resulting from the automatic recovery process performed on the transport vehicles in a state inappropriate for the automatic recovery.

Additionally, this structure allows the transport vehicle determined to be a target of the automatic recovery to resume operating in the same manner as before the electric power supply is interrupted, and thus can appropriately recover the state before the electric power supply is interrupted. The automatic recovery can thus be easily performed on the plurality of transport vehicles.

As described above, this structure can appropriately recover the states of the transport vehicles when the electric power supply to the transport vehicles is interrupted and then restored, and can reduce the likelihood of another failure.

The transporter may include a holder that holds an article, and a mover that moves the holder to transfer the article to and from a transfer area. The mover in each of the plurality of transport vehicles may move the holder to a reference position when the transport vehicle travels and to a transfer position when the article is transferred to and from the transfer area. The operating state information may include holder position information indicating a position of the holder. In response to at least one of the preliminary operating state information or the post-restoration operating state information of a transport vehicle, among the plurality of transport vehicles, including the holder position information indicating that the holder is outside a predetermined allowable range including the reference position, the control system may determine that the transport vehicle is not a target of the automatic recovery in the automatic recovery target determination process.

In this structure, the transport vehicle with its holder not located within the allowable range including the reference position may be excluded from the automatic recovery. Thus, this structure can prevent the transport vehicle with its holder located at a position distant from the reference position from being automatically recovered and starting traveling. This can reduce the likelihood of the automatic recovery causing, for example, damage or a failure in the transport vehicle or the article transported by the transport vehicle.

The transporter may include a traveler that travels along a travel path and an obstacle detector that detects an obstacle on the travel path. The control system may switch a mode of each of the plurality of transport vehicles between an automatic mode in which the traveler travels to a set destination and stops traveling while the obstacle detector is detecting an obstacle and a manual mode in which the traveler travels based on a command from an operation terminal operated by a manager. The operating state information of each of the plurality of transport vehicles may include travel mode information indicating the mode of the transport vehicle. In response to at least one of the preliminary operating state information or the post-restoration operating state information of a transport vehicle, among the plurality of transport vehicles, including the travel mode information indicating that the transport vehicle is in the manual mode, the control system may determine that the transport vehicle is not a target of the automatic recovery in the automatic recovery target determination process.

In this structure, the transport vehicle that is not in the automatic mode may be excluded from the automatic recovery. Thus, the structure can automatically and appropriately recover the transport vehicles other than, for example, a transport vehicle subjected to maintenance or a transport vehicle to be recovered manually. In the automatic mode, the transport vehicle stops traveling while the obstacle is being detected. Thus, the transport vehicle is less likely to, for example, come in contact with the obstacle during the automatic recovery.

The transporter may include an obstacle detector that detects an obstacle on a travel path on which the plurality of transport vehicles travel. The operating state information may include obstacle detection information indicating a detection state of the obstacle detector. In response to at least one of the preliminary operating state information or the post-restoration operating state information of a transport vehicle, among the plurality of transport vehicles, including the obstacle detection information indicating that an obstacle is detected, the control system may determine that the transport vehicle is not a target of the automatic recovery in the automatic recovery target determination process.

In this structure, the transport vehicle detecting the obstacle may be excluded from the automatic recovery. This can reduce the likelihood of damaging the transport vehicle or the article held by the transport vehicle due to, for example, the transport vehicle coming in contact with the obstacle during the automatic recovery.

The transporter may include a traveler that travels along a travel path. The operating state information of each of the plurality of transport vehicles may include traveling position information indicating a position of the transport vehicle on the travel path. The traveling position information included in the preliminary operating state information may be preliminary traveling position information. The traveling position information included in the post-restoration operating state information may be post-restoration traveling position information. In response to a difference between a position indicated by the preliminary traveling position information and a position indicated by the post-restoration traveling position information of a transport vehicle, among the plurality of transport vehicles, being greater than or equal to a predetermined determination threshold, the control system may determine that the transport vehicle is not a target of the automatic recovery in the automatic recovery target determination process.

In this structure, when the difference between the position of the transport vehicle when the electric power supply is interrupted and the position of the transport vehicle after the electric power supply is restored is greater than or equal to the determination threshold, the transport vehicle may be excluded from the automatic recovery. Thus, for example, the transport vehicle moved manually after the electric power supply from the power feeder is interrupted may be excluded from the automatic recovery.

The transport facility may further include detectable members at a plurality of predetermined positions on a travel path. The transporter may include a traveler that travels along the travel path and a detector that detects the detectable members. The traveler may include a drive wheel, a drive that drives the drive wheel, and a rotation position detector that detects a position of the drive wheel in a rotation direction. The operating state information of each of the plurality of transport vehicles may include traveling position information indicating a position of the transport vehicle on the travel path. The traveling position information included in the preliminary operating state information may be preliminary traveling position information. The traveling position information included in the post-restoration operating state information may be post-restoration traveling position information. The control system may control, in response to the electric power supply being interrupted, the drive to stop the drive wheel before the drive stops operating. The control system may identify a stop position of the drive wheel based on a detection result from the detector and a detection result from the rotation position detector, and store, as the preliminary traveling position information, the identified stop position of the drive wheel and the detection result from the rotation position detector. The control system may obtain, after the electric power supply is restored, the detection result from the rotation position detector as the post-restoration traveling position information in response to the preliminary traveling position information being stored. The control system may determine, in response to a difference between the detection result from the rotation position detector included in the preliminary traveling position information and the detection result from the rotation position detector included in the post-restoration traveling position information of a transport vehicle, among the plurality of transport vehicles, being greater than or equal to a predetermined setting value, that the transport vehicle is not a target of the automatic recovery in the automatic recovery target determination process. The control system may identify, for the transport vehicle determined to be a target of the automatic recovery through the automatic recovery target determination process, the stop position of the drive wheel after the electric power supply is restored based on the stop position of the drive wheel included in the preliminary traveling position information and the difference between the detection result from the rotation position detector included in the preliminary traveling position information and the detection result from the rotation position detector included in the post-restoration traveling position information.

This structure can control the transport vehicle to stop automatically before the drive stops operating when the electric power supply from the power feeder is interrupted. The structure can also identify the stop position of the transport vehicle based on position information of the detectable member and the detection result from the rotation position detector and store the identified position as the preliminary traveling position information. The structure can also identify, for the transport vehicle determined to be a target of the automatic recovery, the stop position of the drive wheel after the electric power supply is restored based on the preliminary traveling position information stored as described above. Thus, the position of the transport vehicle determined to a target of the automatic recovery can be determined appropriately in the automatic recovery.

In this structure, the transport vehicle may be excluded from the automatic recovery when the difference between the detection results from the rotation position detector included in the preliminary traveling position information and in the post-restoration traveling position information is greater than or equal to the predetermined setting value. Thus, for example, the transport vehicle manually moved to a different stop position before the automatic recovery may be excluded from the automatic recovery.

The transport facility may further include detectable members at a plurality of predetermined positions on a travel path. The transporter may include a traveler and a detector that detects the detectable members. The traveler may include a drive wheel and a drive that drives the drive wheel to travel along the travel path. The control system may transmit, in the automatic recovery process, a reconstruction command to reconstruct the preliminary operating state information to a target transport vehicle as a transport vehicle, among the plurality of transport vehicles, determined to be the target of the automatic recovery through the automatic recovery target determination process. The control system may cause the target transport vehicle with the reconstructed preliminary operating state information to start traveling, and control the traveling target transport vehicle to travel at a speed lower than a normal speed of traveling without interruption of the electric power supply until the target transport vehicle detects a first detectable member among the detectable members.

In this structure, the target transport vehicle reconstructs the preliminary operating state information in the automatic recovery process, and can thus determine, for example, information about its traveling position stored before the interruption and information about the holding state of an article (whether an article is held). Thus, the target transport vehicle can be automatically recovered appropriately and can resume transporting the article appropriately.

In this structure, the traveling target transport vehicle travels at a speed lower than the normal speed of traveling until a first detectable member is detected. Thus, the target transport vehicle is less likely to collide with, for example, another target transport vehicle undergoing the automatic recovery or a transport vehicle that is not a target of the automatic recovery.

The transport facility according to one or more embodiments of the disclosure produces at least one of the effects described above.

What is claimed is:

1. A transport facility, comprising:
a plurality of transport vehicles configured to transport articles;
a control system configured to control the plurality of transport vehicles; and
a power feeder configured to supply electric power to the plurality of transport vehicles and the control system, and
wherein:
each of the plurality of transport vehicles comprises a transporter operable to transport the articles,
the control system is configured to obtain operating state information indicating an operating state of the transporter in each of the plurality of transport vehicles,
the control system is configured to perform:
in response to electric power supply to the plurality of transport vehicles being interrupted, an interruption information obtaining process of obtaining the operating state information of each of the plurality of transport vehicles as preliminary operating state information and storing the obtained preliminary operating state information within a period after the electric power supply is interrupted and before the transporter stops operating,
after the electric power supply is restored, a post-restoration information obtaining process of obtaining the operating state information of each of the plurality of transport vehicles as post-restoration operating state information,
an automatic recovery target determination process of determining whether each of the plurality of transport vehicles is a target of automatic recovery based on a result of comparison between the preliminary operating state information and the post-restoration operating state information, and
an automatic recovery process of controlling, among the plurality of transport vehicles, a transport vehicle determined to be the target of the automatic recovery through the automatic recovery target determination process, and causing the transport vehicle to resume operating in a same manner as before the electric power supply is interrupted.

2. The transport facility according to claim 1, wherein:
the transporter comprises a holder configured to hold an article, and a mover configured to move the holder to transfer the article to and from a transfer area,
the mover in each of the plurality of transport vehicles moves the holder to a reference position when the transport vehicle travels and to a transfer position when the article is transferred to and from the transfer area,
the operating state information comprises holder position information indicating a position of the holder, and
in response to at least one of the preliminary operating state information or the post-restoration operating state information of a transport vehicle, among the plurality of transport vehicles, including the holder position information indicating that the holder is outside a predetermined allowable range including the reference position, the control system determines that the transport vehicle is not a target of the automatic recovery in the automatic recovery target determination process.

3. The transport facility according to claim 1, wherein:
the transporter comprises a traveler configured to travel along a travel path and an obstacle detector configured to detect an obstacle on the travel path,
the control system switches a mode of each of the plurality of transport vehicles between an automatic mode in which the traveler travels to a set destination and stops traveling while the obstacle detector is detecting an obstacle and a manual mode in which the traveler travels based on a command from an operation terminal operated by a manager,
the operating state information of each of the plurality of transport vehicles comprises travel mode information indicating the mode of the transport vehicle, and
in response to at least one of the preliminary operating state information or the post-restoration operating state information of a transport vehicle, among the plurality of transport vehicles, including the travel mode information indicating that the transport vehicle is in the manual mode, the control system determines that the transport vehicle is not a target of the automatic recovery in the automatic recovery target determination process.

4. The transport facility according to claim 1, wherein:
the transporter comprises an obstacle detector configured to detect an obstacle on a travel path on which the plurality of transport vehicles travel,
the operating state information comprises obstacle detection information indicating a detection state of the obstacle detector, and
in response to at least one of the preliminary operating state information or the post-restoration operating state information of a transport vehicle, among the plurality of transport vehicles, including the obstacle detection information indicating that an obstacle is detected, the control system determines that the transport vehicle is not a target of the automatic recovery in the automatic recovery target determination process.

5. The transport facility according to claim 1, wherein:
the transporter comprises a traveler configured to travel along a travel path,
the operating state information of each of the plurality of transport vehicles comprises traveling position information indicating a position of the transport vehicle on the travel path,
the traveling position information included in the preliminary operating state information is preliminary traveling position information, and the traveling position information included in the post-restoration operating state information is post-restoration traveling position information, and
in response to a difference between a position indicated by the preliminary traveling position information and a position indicated by the post-restoration traveling position information of a transport vehicle, among the plurality of transport vehicles, being greater than or equal to a predetermined determination threshold, the control system determines that the transport vehicle is not a target of the automatic recovery in the automatic recovery target determination process.

6. The transport facility according to claim 1, further comprising:
detectable members at a plurality of predetermined positions on a travel path, and
wherein:
the transporter comprises a traveler configured to travel along the travel path and a detector configured to detect the detectable members,
the traveler comprises a drive wheel, a drive configured to drive the drive wheel, and a rotation position detector configured to detect a position of the drive wheel in a rotation direction,
the operating state information of each of the plurality of transport vehicles includes traveling position information indicating a position of the transport vehicle on the travel path,
the traveling position information includes in the preliminary operating state information is preliminary traveling position information, and the traveling position information included in the post-restoration operating state information is post-restoration traveling position information,
the control system controls, in response to the electric power supply being interrupted, the drive to stop the drive wheel before the drive stops operating, and
identifies a stop position of the drive wheel based on a detection result from the detector and a detection result from the rotation position detector, and stores, as the preliminary traveling position information, the identified stop position of the drive wheel and the detection result from the rotation position detector,
obtains, after the electric power supply is restored, the detection result from the rotation position detector as the post-restoration traveling position information in response to the preliminary traveling position information being stored, and determines, in response to a difference between the detection result from the rotation position detector included in the preliminary traveling position information and the detection result from the rotation position detector included in the post-restoration traveling position information of a transport vehicle, among the plurality of transport vehicles, being greater than or equal to a predetermined setting value, that the transport vehicle is not a target of the automatic recovery in the automatic recovery target determination process, and
identifies, for the transport vehicle determined to be a target of the automatic recovery through the automatic recovery target determination process, the stop position of the drive wheel after the electric power supply is restored based on the stop position of the drive wheel included in the preliminary traveling position information and the difference between the detection result from the rotation position detector included in the preliminary traveling position information and the detection result from the rotation position detector included in the post-restoration traveling position information.

7. The transport facility according to claim 1, further comprising:
detectable members at a plurality of predetermined positions on a travel path, and
wherein:
the transporter comprises a traveler and a detector configured to detect the detectable members, and the traveler comprises a drive wheel and a drive configured to drive the drive wheel to travel along the travel path,
the control system transmits, in the automatic recovery process, a reconstruction command to reconstruct the preliminary operating state information to a target transport vehicle as a transport vehicle, among the plurality of transport vehicles, determined to be the target of the automatic recovery through the automatic recovery target determination process, and
the control system causes the target transport vehicle with the reconstructed preliminary operating state information to start traveling, and controls the traveling target transport vehicle to travel at a speed lower than a normal speed of traveling without interruption of the electric power supply until the target transport vehicle detects a first detectable member among the detectable members.
